(19) United States
(12) Patent Application Publication
(10) Pub. No.: US 2026/0267214 A1
(43) Pub. Date: Sep. 10, 2026

(54) METHOD FOR PRODUCING A SURFACE COATING WHICH REFLECTS EUV RADIATION

(71) Applicant: Carl Zeiss SMT GmbH, Oberkochen (DE)

(72) Inventor: Sebastian STROBEL, Aalen (DE)

(21) Appl. No.: 19/671,550

(22) Filed: May 8, 2026

Related U.S. Application Data
(63) Continuation of application No. PCT/EP2024/081270, filed on Nov. 6, 2024.

(30) Foreign Application Priority Data
Nov. 10, 2023 (DE) 10 2023 211 114.4

(51) Int. Cl. G03F 1/24

(52) U.S. Cl. CPC G03F 1/24

(57) ABSTRACT

A method for producing a surface coating (200), which reflects extreme-ultraviolet radiation, on a substrate (300). The surface coating (200) has a multilayer system (210) and the substrate (300) has a micro-electromechanical system on the face provided with the surface coating (200). The method includes: a) producing the surface coating (200) on a support (100) in the inverse order of the layers of the multilayer system (210); b) connecting the produced surface coating (200) to the substrate (300) on the face remote from the support (100); and c) releasing and removing the support (100) from the surface coating (300).

### CROSS-REFERENCE TO RELATED APPLICATION

This is a Continuation of International Application PCT/EP2024/081270, which has an international filing date of Nov. 6, 2024, and the disclosure of which is incorporated in its entirety into the present Continuation by reference. This Continuation also claims foreign priority under 35 U.S.C. § 119(a)-(d) to and also incorporates by reference, in its entirety, German Patent Applications DE 10 2023 211 114.4 filed on Nov. 10, 2023.

### FIELD

The invention relates to a method for producing an EUV-radiation-reflective surface coating, in particular for EUV photolithography.

### BACKGROUND

Photolithography is used for producing microstructured components, such as e.g. integrated circuits. The projection exposure apparatus used in the process comprises an illumination system and a projection system. The image of a mask (also referred to as a reticle) illuminated by the illumination system is projected so as to reduce the size of the mask image onto a substrate, for example a silicon wafer. The substrate is coated with a light-sensitive layer and is arranged in the image plane of the projection system. The projection system is used to transfer the image on the mask structure to the light-sensitive coating of the substrate.

In projection exposure apparatuses that operate using exposure radiation in the extreme ultraviolet (EUV) range, the various optical elements in the exposure and projection systems are configured as mirrors with a reflective surface. On account of the wavelengths of the EUV exposure radiation of 5 nm to 30 nm, the optically effective surfaces of the individual elements should be equipped with a multilayer system in order to attain the desired reflectivity.

Moreover, illumination systems, especially in projection exposure apparatuses configured for the EUV range, generally contain two facet mirrors that are arranged in the beam path between the actual exposure radiation source and the mask to be illuminated. The closer facet mirror in the beam path of the exposure radiation source is often a so-called field facet mirror, and the other facet mirror is a so-called pupil facet mirror.

In order to be able to produce different intensity and/or angle of incidence distributions during the illumination of the mask, it is known for the facets of at least one of the two facet mirrors—in particular those of the field facet mirror—to be formed from one or more micromirrors that are electromechanically pivotable on an individual basis. The same is correspondingly disclosed e.g. in WO 2012/130768 A2. Each of these micromirrors should also be provided with a reflective coating.

The multilayer system required for the desired reflectivity is sensitive as a matter of principle and—following its production on surfaces of an optical element provided to this end—might be damaged in subsequent production steps that are required for the completion of the optical element, as a result of which the optical element then becomes unusable or has to be reworked with much outlay. The risk of damage is particularly high in the case micromirror arrangements since the micromirrors are generally in the form of microelectromechanical systems (MEMS), which combine micromechanical structures and electronic elements in one chip.

In the completed state, the micromirrors of a corresponding system can be pivoted about two axes with respect to a base, with a sufficient number of actuators and sensors also being provided in that case to enable independent pivoting of the mirror element about precisely these axes and in order to allow monitoring of this pivoting. In order to be able to apply the multilayer system with the required precision, the base structure of the individual micromirrors should still be fixed and not be pivotable; the steps required for the release of the micromirrors or for allowing these to pivot may damage the multilayer system already applied to the base structure in this case.

### SUMMARY

One object addressed by the present invention is to develop an improved method for producing an EUV-radiation-reflective surface coating, the improvement being in relation to the prior art.

This and other objects are addressed by the method as claimed in the independent claims. The dependent claims relate to advantageous developments.

According to one formulation of the invention, a method for producing an EUV-radiation-reflective surface coating on a substrate is provided. The surface coating comprises a multilayer system and the substrate comprises a microelectromechanical system on the side to which the surface coating should be applied. The method includes:
a) producing the surface coating, with the sequence of layers in the multilayer system in reverse, on a carrier;
b) connecting the produced surface coating at the side remote from the carrier to the substrate; and
c) detaching and removing the carrier from the surface coating.

One aspect of the invention makes use of an insight that, during the state-of-the-art production of a multitude of optical elements for EUV applications, a required multilayer system for reflecting EUV radiation must already be applied at such an early stage during the production process that said multilayer system might be damaged by required subsequent production steps in relation to the optical element; in addition to mechanical processing of the optical elements during the production, which also has a direct effect on an already applied multilayer system, for example the separation of an already coated substrate, this also includes processes in which a required process gas, for example required for etching, may come into contact with, and thereby damage the multilayer system, even if only unintentionally. New possibilities, which cannot be realized in the prior art, arise for the production of optical elements with a corresponding surface coating by virtue of the invention providing for the eventual surface coating of a substrate comprising an appropriate multilayer system to be initially produced separately from said substrate on a carrier and to be then applied to the substrate as a whole, before the carrier is subsequently removed and leaves a substrate provided with the surface coating as the result. On account of the method according to the invention for producing an EUV-radiation-reflective surface coating on a substrate, it is regularly possible to apply the surface coating at a later stage in the production process for an optical element than during a direct production of the multilayer system on the substrate according to the prior art, whereby the risk of damage due to subsequent production steps can be reduced or possibly even completely avoided.

To ensure that the multilayer system does in fact also form the desired surface coating of the substrate at the end of the method, the individual layers of the multilayer system should be produced on the carrier in the reverse order. The layer closest to the carrier when surface coating of the substrate is secured to the carrier forms the outer layer of said surface coating in the completed state. Conversely, the exposed layer of the multilayer system when the latter is arranged on the carrier serves for connection to the substrate and is consequently the closest layer to the substrate in the completed state.

Should the surface coating be arranged on the carrier accordingly with the layers of the multilayer system in reverse, the exposed side of the surface coating remote from the carrier can be connected to the substrate, which is the ultimate intended target of the surface coating, in a next step.

Finally, the carrier is still removed in order thus to expose the surface coating arranged on the substrate and thus also actually attain the desired reflectivity of the substrate in the region of the surface coating.

It is possible that the surface coating is initially constructed with the “usual” sequence of layers of the multilayer system on an initial carrier or initial substrate. Subsequently, the surface coating thus constructed is secured on the carrier according to the invention “upside down” before the initial carrier or the initial substrate is removed in a suitable manner. An advantage of producing the surface coating on a carrier in this way with the multilayer system in reverse is that it is possible to resort to fundamentally known and tried-and-tested production methods for corresponding multilayer systems. In particular, this also applies to the layer which is arranged adjacent to the carrier in the secured-to-carrier state and which is located on the outside of the substrate in the state after the carrier has been removed; this means that the surface quality of said layer can be ensured using known production methods.

However, it is preferable for the surface coating to be produced on the carrier layer by layer, i.e. for the individual layers of the multilayer system to be successively applied to the carrier in reverse. In that case, an initial carrier or initial substrate can be dispensed with, meaning that possible steps for removing these elements only required at the outset are also dispensed with. In principle, methods known from the prior art for producing multilayer systems can also be used in this case.

In order to obtain a sufficiently high surface quality of the outer layer of the multilayer system in the completed state, it is preferable to ensure a high surface quality of the carrier, on which the layer in question initially comes to rest when the surface coating is produced, through suitable processing. A high surface quality of the carrier is desirable, especially when the surface coating is brought about by layer-by-layer application of the individual layers of the multilayer system to the carrier itself, since the surfaces of the carrier may become impressed—at least in the layers of the multilayer system arranged adjacent to the carrier—in a manner comparable to a negative. It is therefore preferable to process the surface of the carrier by applying a smoothing layer, polishing and/or cleaning. The processing methods of polishing and cleaning the surface require no further explanation. Rather, a person skilled in the art can easily ascertain polishing and cleaning methods suitable for the carrier or the material thereof and can also, where necessary, verify the results of these methods. It may be advantageous to apply a smoothing layer to the carrier if the carrier or the material thereof is not suitable for processing that leads to a desired high surface quality itself. This smoothing layer is a layer which either provides the desired surface quality immediately after application or else—possibly unlike the carrier or the material thereof itself—can be processed to lead to the desired surface quality with suitable methods, such as polishing and/or cleaning. Independently of the potential provision of a smoothing layer and the specific surface processing method optionally used, it is preferable for the surface of the carrier in the region provided for the surface coating to have a root-mean-square roughness of 0.2 nm RMS or less and/or an absence of foreign particles larger than 5 μm, preferably larger than 1 μm. Suitable methods and equipment for checking compliance with corresponding specifications are known.

To facilitate detachment and removal of the carrier from the surface coating after this surface coating was connected to the substrate, it may be the case that there is a separation layer between the carrier and the surface coating, at which the carrier can be detached more easily and in damage-free manner from the surface coating. If the surface coating is applied directly to the surface of the carrier or a possible smoothing layer, then the surface coating might only be detached with difficulty, depending on the materials of the coating and the carrier or smoothing layer, as a result of which there is a risk of damage to the surface coating when the carrier is detached. In such a case in particular, a separation layer can reduce or completely avoid the risk of damage to the surface coating. In this case, the separation layer can be designed such that it itself can easily be detached from the carrier or from the surface coating, at least in the latter case also without damaging the surface coating. Alternatively, the separation layer can also be designed such that the destruction of its own structure enables a separation of the carrier and surface coating. The residues of the separation layer remaining on the surface coating in this case or the complete separation layer in the case of a separation between the separation layer and the carrier still need to be removed from the surface coating, either directly or at a later stage. The separation layer can be in the form of a separate layer made of a suitable material when it is applied to the carrier; however, it is also possible for the separation layer to be formed by a chemical reaction on the surface of the carrier itself. For example, if the carrier is made of silicon, the separation layer can be made of silicon oxide, which forms directly on the surface of the carrier when the surface of the carrier comes into contact with air.

A protective layer is preferably provided between the carrier and the surface coating, and it remains on the surface coating after the carrier has been detached and removed from the surface coating and is only removed from the surface coating at a later stage. A corresponding protective layer is capable of protecting the surface coating during method steps that follow the method according to the invention in the production of an optical element or the installation thereof, for example in a projection exposure apparatus. In this context, the protective layer should be configured such that it can easily be removed from the surface coating at a later stage in order to thus expose the actual surface coating with the reflective properties. In this case, removing the protective layer should not damage the surface coating.

If the substrate on which a surface coating should be provided has structuring, i.e. it is not continuous in particular, then it may be advantageous if the surface coating on the carrier is already subdivided into regions that match the structuring of the substrate. For example, if the adjacently arranged micromirrors of a micromirror unit should be provided with a surface coating, then the surface coatings for the individual micromirrors can be provided as separate sections of the surface coating on a shared carrier and can be transferred together to the substrate or the individual micromirrors.

In order to achieve this, before the surface coating is applied, the surface of the carrier may comprise a structuring adapted to the surface of the substrate so that the surface coating to be applied thereto is formed in a manner suitable for connection to a substrate only in predetermined regions. In other words, the surface of the carrier may comprise e.g. recessed regions, in which either no surface coating is produced at all or any potentially produced surface coating is recessed to such an extent that it is not connected to the substrate when the non-recessed regions are connected to the substrate and, in particular, it is removed together with the carrier in one of the subsequent steps.

Especially when the surface coating is produced on the carrier layer by layer, it is preferable for the structure edges in the structuring of the surface of the carrier to be configured to be overhanging. By virtue of an angle of more than 90°, preferably of more than 120°, being made between the surface regions of the carrier to be provided with a surface coating and the side walls delimiting these, as a result of which the respective edges have an overhanging configuration, a sharp and clear delimitation of individual regions with surface coating can regularly be ensured even in the case of layer-by-layer production of the surface coating on the carrier since the risk of enclosing an edge is minimized.

As an alternative to creating a directly structured surface coating through suitable structuring of the carrier before the surface coating is produced thereon, it is also possible to structure the surface coating and/or the top side of the carrier, after the surface coating was produced, adapted to the surface of the substrate. For example, this allows a surface coating initially produced in a continuous manner to be divided into suitable regions and hence be structured using sawing or milling methods.

It may be the case that the surface coating is integrally bonded to the substrate in order to connect the surface coating to the substrate. For this purpose, use can be made of a suitable bonding material where necessary. It is also possible that the surface coating is connected to the substrate with an additive application of the substrate to the surface coating produced on the carrier, with functional layers being able to be applied to the side of the substrate facing away from the surface coating.

Once an EUV-radiation-reflective surface coating has been produced according to the invention on the substrate, the substrate may be or become curved. For example, it may be prestressed to this end, such that the shape of the substrate is changed when the carrier is removed, with, in particular, there also being a change in the shape of the surface of the substrate provided with the surface coating. Alternatively, the substrate can be curved using other known methods after the surface coating has been produced thereon.

A spacer used to reduce the contact area of the substrate with an overarching assembly can be provided on the side of the substrate facing away from the surface coating. Reducing the contact area also reduces the risk of the overarching component introducing stresses into the substrate and/or its surface coating.

The multilayer system is preferably configured to reflect radiation having a wavelength of 1 to 20 nm, preferably of 13.5 nm. Corresponding multilayer systems are known from the prior art and generally comprise alternating layers of molybdenum and silicon.

The substrate comprises a microelectromechanical system on the side of the substrate to which the surface coating should be applied. In this case, the microelectromechanical system can comprise micromirrors, in particular, as used in apparatuses for semiconductor technology.

In this context, “apparatus for semiconductor technology” denotes any apparatus that can be used for the production or testing of microstructured component parts or the components required for this purpose. Besides photolithographic projection exposure apparatuses, this in particular also encompasses inspection apparatuses and metrology systems. In the case of inspection apparatuses for masks or wafers, e.g. the variability of the illumination can be increased with one or more MEMS micromirror units, which can result in higher-contrast or totally new image representations of the surface of a mask or wafer, which can be advantageous for the inspection of mask or wafer. This comparably also applies to metrology systems that can be used to measure masks, wafers or any other optical elements, such as mirrors, in particular, in which case an increased variability in the illumination can improve the measurement results.

### BRIEF DESCRIPTION OF THE DRAWINGS

The invention will now be described by way of example on the basis of exemplary embodiments with reference to the accompanying drawings, in which:

FIG. 1: shows a schematic illustration of a photolithographic projection exposure apparatus, comprising optical elements with reflective surface coatings produced according to the invention;

FIGS. 2A-2E: show a schematic illustration of a first exemplary embodiment of a method of producing a surface coating on a carrier, in five respective steps;

FIGS. 3A-3D: show a schematic illustration of a second exemplary embodiment of a method of producing a surface coating on a carrier, in four respective steps;

FIGS. 4A-4D: show a schematic illustration of a first exemplary embodiment of a method of connecting a surface coating to a substrate and removing the carrier, in four respective steps;

FIGS. 5A-5D: show a schematic illustration of a second exemplary embodiment of a method of connecting a surface coating to a substrate and removing the carrier, in four respective steps;

FIGS. 6A-6E: show schematic illustrations of five respective embodiment variants of the method according to the invention for structured substrates; and

FIGS. 7A and 7B: show schematic illustrations of embodiment variants with, respectively, a flat substrate surface and a curved substrate surface in the completed state.

### DETAILED DESCRIPTION

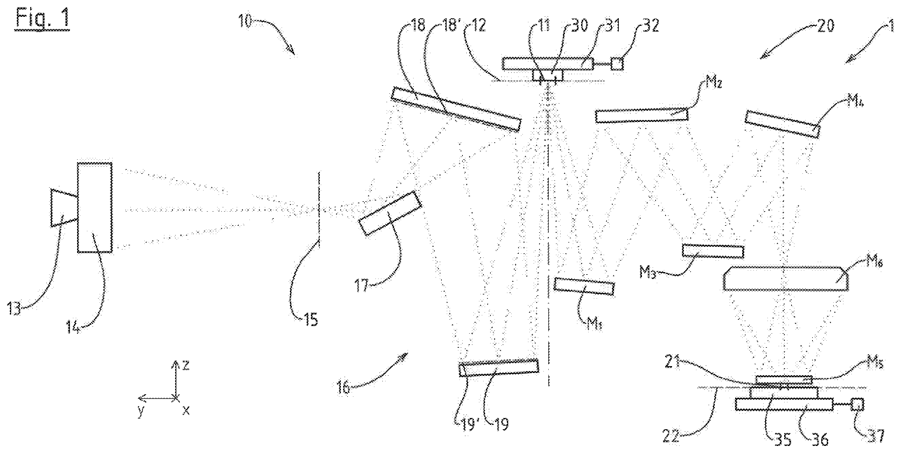

FIG. 1 illustrates a schematic meridional section through a photolithographic projection exposure apparatus 1 as an example of a semiconductor technology apparatus. In this case, the projection exposure apparatus 1 comprises an illumination system 10 and a projection system 20.

An object field 11 in an object plane or reticle plane 12 is illuminated with the illumination system 10. For this purpose, the illumination system 10 comprises an exposure radiation source 13, which, in the illustrated exemplary embodiment, emits illumination radiation at least comprising used light in the EUV range, i.e. with a wavelength of between 5 nm and 30 nm in particular. The exposure radiation source 13 can be a plasma source, for example an LPP (laser produced plasma) source or a GDPP (gas discharge produced plasma) source. It can also be a synchrotron-based radiation source. The exposure radiation source 13 can also be a free electron laser (FEL).

The illumination radiation emerging from the exposure radiation source 13 is initially focused in a collector 14. The collector 14 can be a collector with one or more ellipsoidal and/or hyperboloidal reflection surfaces. The illumination radiation can be incident on the at least one reflection surface of the collector 14 with grazing incidence (GI), i.e. at angles of incidence of greater than 45°, or with normal incidence (NI), i.e. at angles of incidence of less than 45°. The collector 14 can be structured and/or coated on the one hand for optimizing its reflectivity for the used radiation and on the other hand for suppressing extraneous light.

Downstream of the collector 14, the illumination radiation propagates through an intermediate focus in an intermediate focal plane 15. If the illumination system 10 is constructed in a modular design, the intermediate focal plane 15 can be used, in principle, for the separation—including the structural separation—of the illumination system 10 into a radiation source module, comprising the exposure radiation source 13 and the collector 14, and the illumination optics unit 16 described below. In the case of a corresponding separation, the radiation source module and the illumination optics unit 16 then jointly form a modularly constructed illumination system 10.

The illumination optics unit 16 comprises a deflection mirror 17. The deflection mirror 17 can be a plane deflection mirror or alternatively a mirror with a beam-influencing effect going beyond the pure deflection effect. In an alternative to that or in addition, the deflection mirror 17 can be embodied as a spectral filter that separates a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged in a plane of the illumination optics unit 16 which is optically conjugate to the reticle plane 12 as a field plane, then this facet mirror is also referred to as a field facet mirror.

The first facet mirror 18 comprises a multiplicity of micromirrors 18′ that are individually pivotable about two mutually perpendicular axes in each case, for the purpose of controllably forming facets which are each preferably configured with an orientation sensor (not illustrated) for determining the orientation of the micromirror 18′. The first facet mirror 18 is thus a MEMS apparatus, as also described in DE 10 2008 009 600 A1, for example.

A second facet mirror 19 is arranged downstream of the first facet mirror 18 in the beam path of the illumination optics unit 16, with the result that this yields a doubly faceted system, the fundamental principle of which is also referred to as a fly's eye integrator. If the second facet mirror 19—as in the illustrated exemplary embodiment—is arranged in a pupil plane of the illumination optics unit 16, it is also referred to as a pupil facet mirror. However, the second facet mirror 19 can also be arranged at a distance from a pupil plane of the illumination optics unit 16, as a result of which a specular reflector arises from the combination of the first and the second facet mirror 18, 19, for example as described in US 2006/0132747 A1, EP 1 614 008 B1 and U.S. Pat. No. 6,573,978.

The second facet mirror 19 need not in principle be constructed from pivotable micromirrors but rather can comprise individual facets formed from one mirror or a manageable number of mirrors which are significantly larger than micromirrors, which facets are either stationary or tiltable only between two defined end positions. It is however—as illustrated—also possible, in the second facet mirror 19, to provide a microelectromechanical system having a multiplicity of micromirrors 19′ that are individually pivotable about two mutually perpendicular axes in each case, each preferably comprising an orientation sensor.

The individual facets of the first facet mirror 18 are imaged into the object field 11 via the second facet mirror 19, with this regularly only being approximate imaging. The second facet mirror 19 can be the last beam-shaping mirror or else actually the last mirror for the illumination radiation in the beam path upstream of the object field 11.

In each case one of the facets of the second facet mirror 19 can be assigned to one of the facets of the first facet mirror 18 for the purpose of forming an illumination channel for illuminating the object field 11. This may in particular result in illumination according to the Köhler principle.

The facets of the first facet mirror 18 are imaged overlaid on one another by way of a respective assigned facet of the second facet mirror 19, for the purpose of illuminating the object field 11. Here, the illumination of the object field 11 is as homogeneous as possible. It preferably has a uniformity error of less than 2%. Field uniformity can be achieved by overlaying different illumination channels.

By selecting the ultimately used illumination channels, which is possible with a suitable setting of the micromirrors 18′ of the first facet mirror 18, it is still possible to set the intensity distribution in the entrance pupil of the projection system 20 described below. This intensity distribution is also referred to as illumination setting. Incidentally, it may be advantageous here to arrange the second facet mirror 19 not exactly in a plane that is optically conjugate to a pupil plane of the projection system 20. In particular, the pupil facet mirror 19 can be arranged tilted relative to a pupil plane of the projection system 20, as is described in DE 10 2017 220 586 A1, for example.

In the arrangement of the components of the illumination optics unit 16 as illustrated in FIG. 1, however, the second facet mirror 19 is arranged in an area conjugate to the entrance pupil of the projection system 20. The deflection mirror 17 and the two facet mirrors 18, 19 are arranged tilted both vis-à-vis the object plane 12 and vis-à-vis one another in each case.

In an alternative embodiment (not illustrated) of the illumination optics unit 16, a transfer optics unit comprising one or more mirrors can additionally be provided in the beam path between the second facet mirror 19 and the object field 11. The transfer optics unit can in particular comprise one or two normal-incidence mirrors (NI mirrors) and/or one or two grazing-incidence mirrors (GI mirrors). Using an additional transfer optics unit, it is possible in particular to take account of different poses of the entrance pupil for the tangential and for the sagittal beam path of the projection system 20 described below.

It is alternatively possible for the deflection mirror 17 illustrated in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 via the projection system 20.

For this purpose, the projection system 20 comprises a plurality of mirrors Mᵢ, which are consecutively numbered in accordance with their arrangement in the beam path of the projection exposure apparatus 1.

In the example illustrated in FIG. 1, the projection system 20 comprises six mirrors M₁ to M₆. Alternatives with four, eight, ten, twelve or any other number of mirrors Mᵢ are likewise feasible. The penultimate mirror M₅ and the last mirror M₆ each have a passage opening for the illumination radiation, as a result of which the illustrated projection system 20 is a doubly obscured optical unit. The projection system 20 has an image-side numerical aperture that is greater than 0.3 and can also be greater than 0.6 and can be for example 0.7 or 0.75.

The reflection surfaces of the mirrors Mᵢ can be in the form of free-form surfaces without an axis of rotational symmetry. However, the reflection surfaces of the mirrors Mᵢ can alternatively also be designed as aspherical surfaces with exactly one axis of rotational symmetry of the reflection surface shape. Just like the mirrors of the illumination optics unit 16, the mirrors Mᵢ can also have reflective coatings for the illumination radiation. These reflective coatings can be designed as multilayer coatings, in particular with alternating layers of molybdenum and silicon.

The projection system 20 has a large object-image shift in the y-direction between a y-coordinate of a center of the object field 11 and a y-coordinate of the center of the image field 21. This object-image shift in the y-direction can be of approximately the same magnitude as a z-distance between the object plane 12 and the image plane 22.

In particular, the projection system 20 can be designed to be anamorphic, i.e. it has different imaging scales βₓ, β_{y} in the x- and y-directions in particular. The two imaging scales βₓ, β_{y} of the projection system 20 are preferably (βₓ, β_{y})=(+/−0.25, /+−0.125). An imaging scale β of 0.25 corresponds here to a reduction with a ratio of 4:1, while an imaging scale β of 0.125 results in a reduction with a ratio of 8:1. A positive sign in the case of the imaging scale β means imaging without image inversion; a negative sign means imaging with image inversion.

Other imaging scales are likewise possible. Imaging scales βₓ, β_{y} with the same sign and the same magnitude in the x- and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

In particular, the projection system 20 can comprise a homocentric entrance pupil. This may be accessible. However, it may also be inaccessible.

A reticle 30 (also referred to as mask) arranged in the object field 11 is exposed by the illumination system 10 and the resulting illumination radiation is transferred by the projection system 20 onto the image plane 21. The reticle 30 is held by a reticle holder 31. The reticle holder 31 is displaceable in particular in a scanning direction with a reticle displacement drive 32. In the exemplary embodiment illustrated, the scanning direction runs in the y-direction.

A structure on the reticle 30 is imaged onto a light-sensitive layer of a wafer 35 arranged in the region of the image field 21 in the image plane 22. The wafer 35 is held by a wafer holder 36. The wafer holder 36 is displaceable with a wafer displacement drive 37 in particular along the y-direction. The displacements, firstly, of the reticle 30 with the reticle displacement drive 32 and, secondly, of the wafer 35 with the wafer displacement drive 37 can be synchronized with one another.

In the projection exposure apparatus 1 depicted in FIG. 1 or the illumination system 10 thereof, the above description of which in essence reflects known prior art, the various optical elements that reflect the EUV exposure radiation, i.e. the mirrors or micromirrors 17, 18′, 19′ of the exposure system 10 and the mirrors M₁ to M₆ of the projection system 20, are provided with a surface coating 200 that is reflective to radiation having a wavelength of 1 to 20 nm and is applied to a substrate 300 which forms the structure of the respective optical element at least in part. In this case, the surface coating 200 comprises a multilayer system 210 made of alternately arranged layers of silicon and molybdenum.

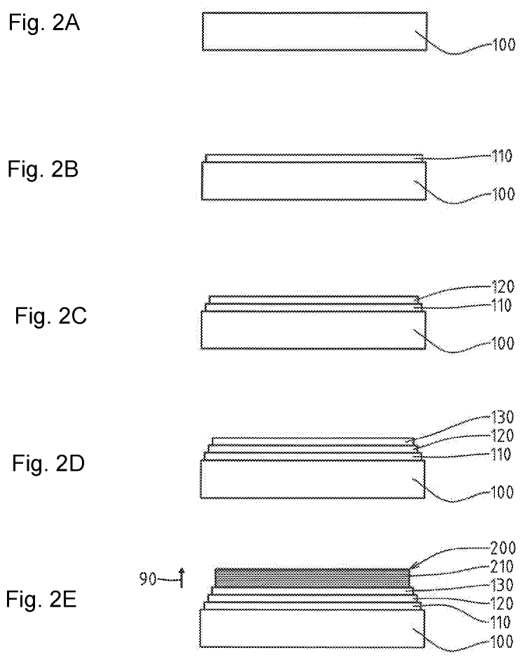

In this case, at least some of the surface coatings 200 of the optical elements 17, 18′, 19′, M₁ to M₆ have been applied to the respective substrates 300 using a method according to the invention. Various embodiments of the method according to the invention will be explained in more detail below on the basis of FIGS. 2A to 7B.

The method according to the invention is distinguished in that the surface coating 200 intended for a substrate 300 is initially produced in its entirety on a carrier 100 before it is subsequently transferred to the substrate 300.

A first exemplary embodiment of the first part of the method according to the invention, specifically the production of the surface coating 200 on a carrier 100, is depicted in FIGS. 2A-2E by way of example.

Starting with a carrier 100 (FIG. 2A) whose surface has been sufficiently cleaned, there is the option of applying a smoothing layer 110 (FIG. 2B) with a surface with a root-mean-square roughness of less than 0.2 μm on the side facing away from the carrier 100. The smoothing layer 110 prevents the surface structure of the carrier 100, even if only on a microscopic scale, from being transferred to the surface coating 200 directly or through other possible intermediate layers (such as the separation layer 120 and protective layer 130 explained below) and the subsequent outer surface of the surface coating 200 from having a negative of the surface structure of the carrier 100. The smoothing layer 110 may already have the desired low roughness immediately after application, for example following curing from a fluid state, or obtain this on account of subsequent processing, e.g. polishing.

If the carrier 100 already inherently has an appropriately low roughness or if an appropriately low roughness can be achieved by surface processing such as polishing, then the smoothing layer 110 can also be dispensed with. Nevertheless, the merely optional smoothing layer 110 is illustrated below as a matter of principle for reasons of clarity.

A separation layer 120 (FIG. 2C) is initially applied to the smoothing layer 110 (or directly to the carrier 100), and this is followed by the application of a protective layer 130 (FIG. 2D). In this case, the separation layer 120 is configured in a manner adapted to the protective layer 130 so that these two layers 120, 130 can easily be detached from one another. The detachment of the layers 120, 130, which takes place at a later time, should in principle be able to be implemented such that neither the protective layer 130 nor other surrounding layers, such as the surface coating 200 in particular, are adversely affected by the detachment. If detachment is implemented solely by the application of a suitable tensile force, then the force required for undoing the connection between the separation layer 120 and the protective layer 130 should be significantly lower than that required to separate the other layers from one another—in particular the layers of the multilayer system 210 in the surface coating 200. If the detachment of the separation layer 120 from the protective layer 130 is caused or assisted by the use of chemicals and/or specific ambient conditions, e.g. certain temperatures, then it is necessary to ensure that the surrounding layers and the surface coating 200 in particular are not damaged by these chemicals and/or ambient conditions.

The protective layer 130 is suitably configured such that it can be removed without residue at a later stage (in particular also after the method according to the invention has been completed). Should the protective layer 130 be removed by chemical means, these should be configured such that the chemicals required for the removal do not attack the surrounding layers and structures—especially the surface coating 200.

Both the separation layer 120 and the protective layer 130 are optional. For example, there is no need for a separation layer 120 if the detachment and removal of the carrier 100 from the surface coating 200, as described below, can be effected without damage to the surface coating 200 even without the corresponding layer, for example because the protective layer 130 applied directly to the smoothing layer 110 can be easily detached from the smoothing layer 110. In particular, the protective layer 130 can be dispensed with in those processes in which a corresponding protective layer 130 would already have to be removed virtually immediately after the detachment and removal of the carrier 100 from the surface coating 200 as described below. In such a case, dispensing with the protective layer 130 can avoid the additional process step for removing the same, possibly without a noticeable increase in the risk of damage to the surface coating 200.

The surface coating 200 is subsequently produced on the protective layer 130. For this purpose, the individual layers of the multilayer system 210 are produced in succession, as indicated by the arrow 90. In this case, the sequence of the layers in the multilayer system 210 is in reverse in comparison with the sequence that is desired in the subsequent surface coating 200 of the substrate 300. In the state following the transfer to the substrate 300, the layer of the multilayer system 210 immediately adjacent to the protective layer 130 is the outer layer that forms the exposed surface of the surface coating 200.

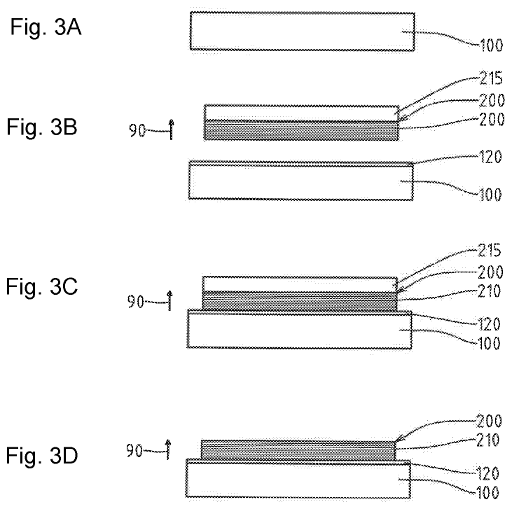

FIGS. 3A-3D illustrate an alternative procedure to the method step of producing the surface coating 200 on a carrier 100 illustrated in FIGS. 2A-2E.

Starting with a carrier 100 (FIG. 3A), a separation layer 120 is formed directly on the carrier 100 (FIG. 3B) as a result of contact with air or a chemical. The formation of the separation layer 120 is optional in this case. Then, the surface coating 200 is applied as a whole to the carrier 100 or the separation layer 120 and is thus produced. To this end, the multilayer system 210 of the surface coating 200 is prepared on an initial substrate 215 using known production methods and in a “normal” layer sequence and is connected to the carrier 100 or the separation layer 120 (FIG. 3C). Subsequently, the initial substrate 215 is removed (FIG. 3D).

The separation layer 120 can also be dispensed with for the reasons explained in the context of FIGS. 2A-2E. Then again, it is for example also possible to provide an additional protective layer 130.

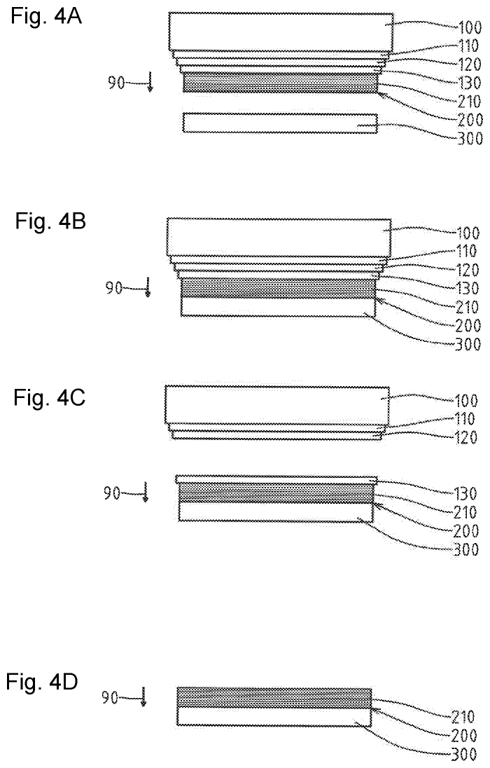

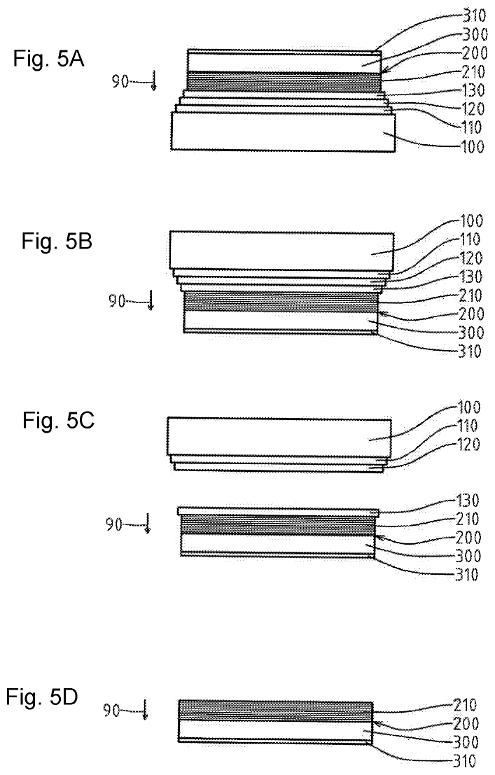

Regardless of how the surface coating 200 or the multilayer system 210 thereof is produced on the carrier 100, the production is followed by connecting the surface coating 200 and detaching and removing the carrier 100, as explained below with reference to FIGS. 4A-5D, which show alternative procedures. For the sake of simplicity, the surface coating 200 produced in accordance with FIGS. 2A-2E is assumed here, even though the method steps shown in FIGS. 4A-5D are also applicable directly to the surface coating produced in accordance with FIGS. 3A-3D.

In order to connect the surface coating 200 produced to the substrate 300 in the region of the substrate to be provided with a surface coating, the surface coating 200 still on the carrier 100 is made to approach the substrate 300 with the side remote from the carrier 100 leading (FIG. 4A) and is integrally bonded to the substrate 300 (FIG. 4B).

Subsequently the carrier 100 is separated from the surface coating 200, wherein a separation is effected between the separation layer 120 and the protective layer 130 in the exemplary embodiment illustrated (FIG. 4C). The protective layer 130 initially remains on the surface coating 200 and is only removed at a later stage, in particular even only after the method according to the invention has been completed (FIG. 4D). As a result of the protective layer 130, the surface coating 200 can be protected from damage, wherein, in that case, the protective layer 130 should also be removed without damage to the surface coating 200.

Incidentally, the arrow 90 for specifying the sequence in which the layers of the multilayer system 210 were produced on the carrier 100 (cf. FIGS. 2A-3D) is shown in FIGS. 4A-4D. It is immediately evident therefrom that the sequence on the carrier 100 is reversed in comparison with the sequence on the substrate 300. Subsequently, the layers on the carrier 100 should thus be produced in a reversed sequence in relation to the layer sequence ultimately desired on the substrate 300.

FIGS. 5A-5D show an alternative procedure to that of FIGS. 4A-4D.

Proceeding from the surface coating 200 produced on the carrier 100, the substrate 300 is subsequently applied directly to the surface coating 200 (FIG. 5A), for which purpose it is possible in particular to resort to methods comparable to those for layer-by-layer application of the individual layers of the multilayer system 210 of the surface coating 200. In particular, the substrate 300 can thus also be applied layer by layer. The procedure shown in FIGS. 5A-5D also allows the provision of functional layers 310 on the side of the substrate 300 facing away from the surface coating 200. The functional layer 310 shown in FIG. 5A by way of example can for example be designed to measure the temperature directly on the substrate 300. However, any other or additional layers, such as the functional layer 310 illustrated can be provided.

A state comparable to the above-described approach (cf. FIGS. 4B and 5B) is present in principle after substrate 300 and possible further layers, such as the functional layer 310, have been produced in full. Thus, in order to explain FIGS. 5C and 5D, reference is made to the explanations above, in particular in relation to FIGS. 4C and 4D.

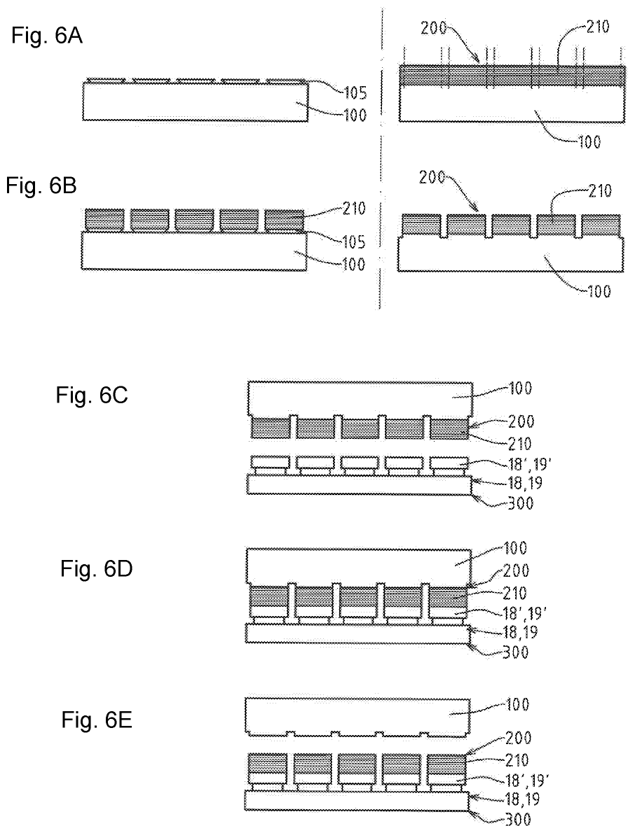

FIGS. 6A-6E show an embodiment variant of the method according to the invention for structured substrates 300, i.e. for substrates 300 whose surface to be provided with a surface coating 200 is not continuous. In relation to a projection exposure apparatus 1, as depicted in FIG. 1, the facet mirrors 18, 19, whose surfaces are formed by a multitude of discrete micromirrors 18′, 19′, can be regarded as such a structured substrate 300, in which the individual mirror surfaces of the micromirrors 18′, 19′ should each be provided with a surface coating 200.

In this case, FIGS. 6A-6E show two possibilities for producing the surface coating 200 (cf. FIGS. 6A, 6B, left/right), while the method steps of connecting the surface coating 200 to the substrate 300 and removing the carrier 100, which follow the production, can be considered together (cf. FIGS. 6C-6E).

In the procedure illustrated on the left-hand side in FIGS. 6A and 6B, the carrier 100 already has a structuring 105 with overhanging structure edges which is adapted to the surface of the substrate 300—i.e. in this case the shape and arrangement of the micromirrors 18′, 19′—already in the initial state (cf. FIG. 6A). During the production of the surface coating, the surface coating 200 is created only in the regions of the structuring 105 in a manner analogous to the procedure shown in FIGS. 2A-2E, i.e. a layer-by-layer construction of the multilayer system 210. In this case, the overhanging structure edges help to avoid unwanted edge effects during the layer-by-layer production of the surface coating 200. The adapted structuring 105 has a height that is greater than the thickness of the coating to be applied. This can effectively prevent material of the multilayer system 210 possibly applied away from the regions that should actually be coated from growing together with the actually desired surface coating 200.

In the procedure illustrated on the right-hand side of FIGS. 6A and 6B, a continuous surface coating 200 is initially produced, e.g. in accordance with FIGS. 2A-2E or 3A-3D, on the carrier 100 (FIG. 6A, right-hand side) and then structured as desired. For structuring purposes, the surface coating 200 can be suitably sawn or etched, for example, wherein structuring right down into the carrier 100 for reliable separation of the individual regions of the surface coating 200 is unproblematic for as long as the structural integrity of the carrier 100 remains ensured as a matter of principle.

Independently of how the surface coating 200 has been structured on the carrier 100, the production thereof is followed by connecting to the substrate 300 and detaching and removing the carrier (cf. FIGS. 6C-6D). In this case, the structuring of the surface coating 200 ensures that each individual micromirror 18′, 19′ is provided with a surface coating in an accurately fitting manner.

Apart from the fact that individual micromirrors 18′, 19′ are provided with the surface coating 200 rather than a continuous structure, the procedure corresponds to that from FIGS. 4C-4E, for which reason the statements given there are referred to for further explanations.

FIGS. 6A-6E do not depict any smoothing, separation or protective layers 110, 120, 130 (cf. FIGS. 2A-5D). However, appropriate layers can be provided if necessary. For more detailed explanations regarding the layers in question, reference is made to the statements above.

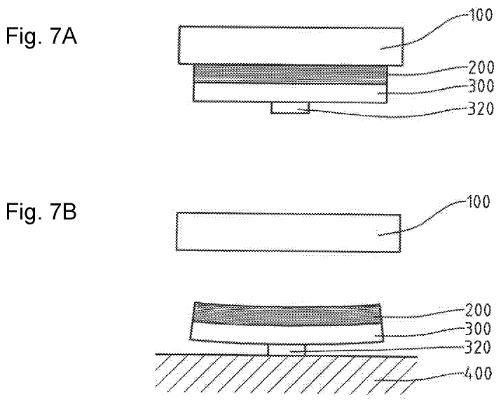

FIGS. 7A and 7B show embodiment variants with a substrate 300 curved in the final state.

Even if the substrate 300 is curved in the final state (cf. FIG. 7B), the surface coating 200, which is produced in any desired manner on a flat carrier 100 (cf. FIGS. 2A-2E and 3A-3D in particular), is applied when the substrate 300 is in a flat state (cf. FIG. 7A). Whether this flat state of the substrate 300 is achieved solely due to contact with the surface coating 200 still situated on the carrier 100, e.g. due to an elastic deformation of the substrate 200, or ensured by other measures is irrelevant.

In any case, the substrate 300 adopts a curved shape, which is also reproduced by the surface coating 200, after the carrier 100 has been detached and removed.

The substrate 300 can be connected to a superordinate component 400. So as not to influence the curvature of the substrate 300, or influence this as little as possible, it is feasible to have the side of the substrate 300 facing away from the surface coating 200 comprise a spacer 320 that is used to connect the substrate 300 to the component 400 in a locally delimited manner. The spacer 320 may be formed in one piece with the substrate 300 or it may be formed as a separate component and then connected to the substrate 300.

The above description of various embodiments has been given by way of example. From the disclosure given, those skilled in the art will not only understand the present invention and its attendant advantages but will also find apparent various changes and modifications to the structures and methods disclosed. The applicant seeks to cover all such changes and modifications as fall within the spirit and scope of the invention, as defined by the appended claims, and equivalents thereof.

What is claimed is:

1. A method for producing an extreme-ultraviolet-radiation-reflective surface coating on a substrate, wherein the surface coating comprises a multilayer system and the substrate comprises a microelectromechanical system on a side of the substrate configured for application of the surface coating, said method comprising:
producing the surface coating with a sequence of layers in the multilayer system on a carrier, wherein the sequence is in an inversed order;
connecting the produced surface coating at a side remote from the carrier to the substrate; and
detaching and removing the carrier from the surface coating,
wherein:
(a) before the surface coating is applied, the surface of the carrier comprises a structuring adapted to the surface of the substrate so that the surface coating to be applied is suited to connect to the substrate only in predetermined regions, or
(b) the surface coating and/or a top side of the carrier are structured, after the surface coating is produced and adapted to the surface of the substrate.

2. The method as claimed in claim 1, wherein
said producing comprises producing the surface coating layer by layer on the carrier.

3. The method as claimed in claim 1, further comprising:
processing the surface of the carrier by applying a smoothing layer to the carrier surface, polishing the carrier surface and/or cleaning the carrier surface.

4. The method as claimed in claim 3, wherein
said processing achieves a roughness of 0.2 nm RMS or less.

5. The method as claimed in claim 1, further comprising:
processing the surface of the carrier by applying a smoothing layer to the carrier surface, polishing the carrier surface and/or cleaning the carrier surface while ensuring an absence of foreign particles larger than 5 μm.

6. The method as claimed in claim 1, further comprising:
providing a separation layer between the carrier and the surface coating, wherein the separation layer improves detachment of the carrier from the surface coating by simplifying the detachment and/or by lessening damage to the surface coating during the detachment.

7. The method as claimed in claim 1, further comprising:
providing a protective layer between the carrier and the surface coating, wherein the surface coating remains on the surface coating after said removing and detaching of the carrier from the surface coating.

8. The method as claimed in claim 1, wherein
in accordance with the alternative (a), structure edges in the structuring of the carrier are configured to be overhanging.

9. The method as claimed in claim 1, wherein
the surface coating is integrally bonded to the substrate.

10. The method as claimed in claim 1, further comprising:
connecting the surface coating to the substrate by an additive application of the substrate to the surface coating produced on the carrier.

11. The method as claimed in claim 10, wherein
functional layers are applied to a side of the substrate facing away from the surface coating.

12. The method as claimed in claim 1, wherein
after said detaching and removing of the carrier, the substrate is or becomes curved.

13. The method as claimed in claim 1, further comprising:
providing a spacer on a side of the substrate facing away from the surface coating.

14. The method as claimed in claim 1, wherein
the multilayer system is configured to reflect radiation having a wavelength of between 1 nm and 20 nm.

15. The method as claimed in claim 1, wherein
the microelectromechanical system comprises micromirrors on a side of the substrate to which the surface coating is applied.
